(19) United States
(12) Patent Application Publication
(10) Pub. No.: US 2012/0094434 A1
(43) Pub. Date: Apr. 19, 2012

(54) ENHANCED SPONTANEOUS SEPARATION METHOD FOR PRODUCTION OF FREE-STANDING NITRIDE THIN FILMS, SUBSTRATES, AND HETEROSTRUCTURES

(76) Inventor: BENJAMIN ALLEN HASKELL, Santa Barbara, CA (US)

(21) Appl. No.: 13/274,197

(22) Filed: Oct. 14, 2011

Related U.S. Application Data
(63) Continuation-in-part of application No. 12/185,607, filed on Aug. 4, 2008, now abandoned.

(51) Int. Cl. H01L 21/20

(52) U.S. Cl. 438/104; 438/478; 257/E21.09

(57) ABSTRACT

The present invention provides a superior method for the removal of nitride semiconductor thin films, thick films, heterostructures, and bulk material from initial substrates and/or templates. The method utilizes specially patterned mask layers between the initial substrates/templates and the nitride semiconductors to decrease adhesion between the nitride semiconductor and underlying material. Thermal stresses generated upon cooling the nitride semiconductor from its deposition temperature trigger spontaneous separation of the nitride semiconductor from the initial substrate or template at the mask layer. The invention dies deficiencies in the prior art by providing a simple, reproducible, and effective means of removing initial substrates and templates from a variety of nitride semiconductor layers and structures.

### CROSS REFERENCE TO RELATED APPLICATIONS

This application is a continuation-in-part of U.S. application Ser. No. 12/185,607 filed Aug. 4, 2008 and is incorporated herein by reference in its entirety.

### TECHNICAL FIELD

The present invention relates to nitride semiconductors in the forms of substrates, thin films, templates, heterostructures and electronic devices based on, incorporating or comprising the nitride semiconductors and methods of making the same.

### BACKGROUND OF THE INVENTION

Gallium nitride and its alloys with indium, aluminum, and boron nitride have attracted significant attention recently due to the successful development of visible and ultraviolet light emitting diodes (LEDs), blue/violet laser diodes, and high-power electronic devices based on this materials system. Revolutions in lighting, display technology, data storage, and power switching are occurring as a result of the unique optical, electronic, and structural properties of this (Al, In, B, Ga)N semiconductor system, collectively referred to hereafter as “nitrides” or “nitride semiconductors” and defined herein below for purposes of the present application. Despite considerable progress, however, devices based on nitride semiconductors, including but not limited to laser diodes, light emitting diodes, photovoltaics, and power transistors (hereafter collectively referred to as “nitride devices”) have failed to attain their theoretical performance potential and have therefore remained too inefficient, too fragile, and/or too expensive for widespread commercial and consumer use.

Three of the major causes of this shortfall in device performance are internal electrical polarization-related inefficiencies of conventional nitride devices, high defect densities in the nitride semiconductors, and poor conductivity of the nitrides. The inventor previously demonstrated a means of eliminating so-called polarization effects via the growth of planar nonpolar nitrides, as described in U.S. patent applications Ser. Nos. 10/537,644, 10/537,385, and 11/140,893, as well as U.S. Pat. No. 7,186,302, which are all incorporated by reference herein in their entirety.

It should be understood that the nonpolar directions and planes of nitride semiconductors are those directions and planes having Miller-Bravais indices described by values hki0, in which h±k+i=0. With reference to FIG. 1 below, nitride semiconductors contain two families of nonpolar directions: the a-directions belonging to the [symbol] 11 2̅0 [symbol] family that includes the [11 2̅0], [1 2̅10], [ 2̅110], [ 1̅ 1̅20], [ 1̅2 1̅0], and [2 1̅ 1̅0] crystallographic directions; and the m-directions belonging to the [symbol] 1 1̅00 [symbol] family that includes the [1 1̅00], [10 1̅0], [01 1̅0], [0 1̅10], [ 1̅010], and [ 1̅00] directions. Further, the nonpolar planes are defined as planes having surface normals parallel to the twelve nonpolar directions indicated above. Thus, when referring to a-plane GaN, reference is made to any plane in the {11 2̅0} family of planes, which includes the (11 2̅0), (1 2̅10), ( 2̅110), ( 1̅ 1̅20), ( 1̅2 1̅0), and (2 1̅ 1̅0) crystallographic planes; likewise, the m-planes include all of the members of the {1 1̅00} family, including the (1 1̅00), (10 1̅0), (01 1̅0), (0 1̅10), ( 1̅010), and ( 1̅100) planes. It should be noted that, neglecting the incorporation of impurities and dopants in the crystal, all nonpolar planes contain nominally equal numbers of group III atoms (e.g. Ga, Al, In, or B) and group V atoms (i.e. nitrogen).

It should further be understood that an alternate family of relevant directions and planes of nitride semiconductors are the basal planes. The two types of basal planes are the (0001) and (000 1̅) planes, which belong to the {0001} family of planes. Both planes in the {0001} family are referred to as “c-planes,” but they are chemically and structurally distinct. The (0001) plane surface contains only group III atoms, whereas the (000 1̅) plane surface contains only group V atoms. The c-planes are also commonly referred to as “polar” planes in nitride semiconductors, The crystallographic directions that are perpendicular to the polar c-planes are the [0001] and [000 1̅] directions, and are referred to as the c-directions.

A further family of relevant planes in nitride semiconductors are the “semipolar” planes, The term “semipolar planes” can be used to refer to a wide variety of planes that possess at least two nonzero h, i, or k Miller indices and a nonzero l Miller index. Some commonly observed examples of semipolar planes include, but are not limited to, the {11 2̅2}, {10 1̅1}, {10 1̅2}, {10 1̅3}, {10 1̅4}, and {20 2̅1} families of planes. These planes are inclined relative to both the nonpolar and polar planes; for example, the {10 1̅1} and {10 1̅3} planes are at 62.98° and 32.06° relative to the c-planes, respectively.

The fabrication of nonpolar and semipolar nitride thick films, templates, substrates, and nitride-based heterostructures via heteroepitaxial methods, meaning growth upon dissimilar templates or substrates, has been widely reported in the literature. These fabrication techniques typically involve growth of a nitride film upon sapphire, silicon carbide, or lithium aluminate substrates, in many cases, such as the production of free-standing nitride substrates or flip-chip mounting of device layers, it is desirable to remove the dissimilar substrate from the nitride structure. Such initial dissimilar substrate removal has previously proven challenging, as the nitride substrates tend to adhere strongly to their initial dissimilar substrates. Also, with the exception of lithium aluminate substrates, the dissimilar substrates commonly used for III-nitride heteroepitaxy commonly possess similar chemical properties to the nitride structure, often complicating or eliminating the possibility of chemically removing the dissimilar substrate, Most dissimilar substrates used for III-nitride heteroepitaxy are also very hard materials (such as silicon carbide and sapphire), making them extremely difficult to remove mechanically.

Some common methods are used to remove dissimilar substrates from nitride structures. Laser lift-off (e.g. Wong, Sands, & Cheung, Appl. Phys. Lett, 72 (5), 1998) provides one method for removal of GaN or some (Al,In,Ga,B)N structures from wider bandgap substrates such as sapphire. However, this process frequently induces cracks or fractures within the nitride being removed, and is difficult and costly to implement at commercially relevant scales. Laser lift-off is also not suitable for removal of dissimilar substrates possessing similar or smaller bandgaps to the nitride structure, making it unable to remove silicon carbide or silicon substrates, for example.

The production of free-standing nitride substrates in particular would greatly benefit from a simple means to remove dissimilar substrates from thick nitride films. In some cases, it would be desirable to be able to remove dissimilar substrates from thinner heteroepitaxially grown nitride structures, such as in flip-chip mounting or for the creation of thin resonant cavities. A preferred dissimilar substrate removal method should minimize cracking or other mechanical or chemical damage to the nitride structure, yielding intact thin or thick nitride films. It would further be preferable if the dissimilar substrate removal method utilized common equipment and/or procedures, thereby minimizing the cost of the removal process.

### SUMMARY OF THE INVENTION

The present invention fulfills these needs and satisfies additional objects and advantages by providing convenient methods for the removal of dissimilar substrates from nitride structures.

The methods of the present invention utilize common semiconductor process equipment and techniques, thereby decreasing the cost of the removal methods compared to the prior art.

The present invention also provides methods for fabrication of free-standing templates and substrates comprising nitride semiconductors that may potentially be utilized in the production of free-standing nitride substrates for subsequent homoepitaxial growth of nitride devices.

For purposes of describing the present invention, the terms “nitride,” “nitride semiconductor,” and “nitride structure” as used herein refer to a semiconductor material containing gallium nitride either alone or in combination with one or more of aluminum nitride, indium nitride and boron nitride, wherein the bulk composition of gallium nitride, aluminum nitride, indium nitride and boron nitride in the semiconductor material is given by the formula (AlₓB_{y}In_{z}Ga_{1-x-y-z})N, in which 0≦x≦1, 0≦y≦1, 0≦z≦1, and 0≦x+y+z≦1. Generically, such nitride semiconductor compositions can be and are sometimes referred to as “AlBInGaN.”

The present invention provides methods to automatically remove dissimilar substrates from nitride structures in conjunction with the growth of those nitride structures to produce free-standing nitride semiconductors. For purposes of describing the present invention, the term “free-standing nitride semiconductor” as used herein refers to a nitride semiconductor that has been separated from the substrate or template and mask material on which it is grown. The methods of the present invention utilize thermal expansion mismatches between the nitride structure and the dissimilar substrate, coupled with creation of a reduced surface area interface between the nitride structure being grown and the underlying dissimilar substrate or template. Properly implemented, the invention provides methods by which the dissimilar substrate spontaneously separates from the nitride structure upon cooling from the nitride growth process.

In one embodiment, the present invention provides a method for the production of a free-standing nitride semiconductor comprising: selecting an initial substrate that is suitable for growth of a desired nitride semiconductor; depositing a mask material that provides growth selectivity for the nitride semiconductor on the initial substrate; producing a pattern of exposed initial substrate regions within the mask material; selectively growing the nitride semiconductor through and over the openings in the mask material; and cooling the nitride semiconductor from its deposition temperature, whereby the nitride semiconductor separates from the initial substrate.

Various products can be prepared using the methods of the present invention.

The most basic product embodiment utilizing the present invention is the creation of a free-standing, nonpolar a-plane gallium nitride substrate via spontaneous separation.

An alternate product embodiment utilizing the present invention is the creation of a free-standing, nonpolar in-plane gallium nitride substrate via spontaneous separation.

Another alternate product embodiment utilizing the present invention is the creation of a free-standing, nonpolar a-plane aluminum nitride substrate via spontaneous separation.

An additional alternate product embodiment utilizing the present invention is the creation of a free-standing, nonpolar m-plane aluminum nitride substrate via spontaneous separation.

A further alternate product embodiment utilizing the present invention is the creation of a free-standing, semipolar gallium nitride substrate via spontaneous separation.

Another alternate product embodiment utilizing the present invention is the creation of a free-standing, semipolar aluminum nitride substrate via spontaneous separation.

An additional alternate product embodiment utilizing the present invention is the creation of a free-standing, nonpolar a-plane AlGaInBN alloy substrate via spontaneous separation.

A further alternate product embodiment utilizing the present invention is the creation of a free-standing, nonpolar m-plane AlGaInBN alloy substrate via spontaneous separation.

Another alternate product embodiment utilizing the present invention is the creation of a free-standing, semipolar AlGaInBN alloy substrate via spontaneous separation.

An additional alternate product embodiment utilizing the present invention is the creation of a thin nitride AlGaInBN membrane via spontaneous separation.

A further alternate product embodiment utilizing the present invention is the creation of a thin nitride heterostructure membrane via spontaneous separation.

Another alternate product embodiment utilizing the present invention is the creation of a thin nitride resonant cavity structure via spontaneous separation.

### BRIEF DESCRIPTION OF THE DRAWINGS

Preferred and alternative embodiments of the present invention are described in detail below with reference to the following drawings.

FIG. 1 shows examples of a nitride semiconductor crystal structure and primary crystallographic directions, along with examples of nonpolar, polar, and semipolar planes of nitride semiconductors.

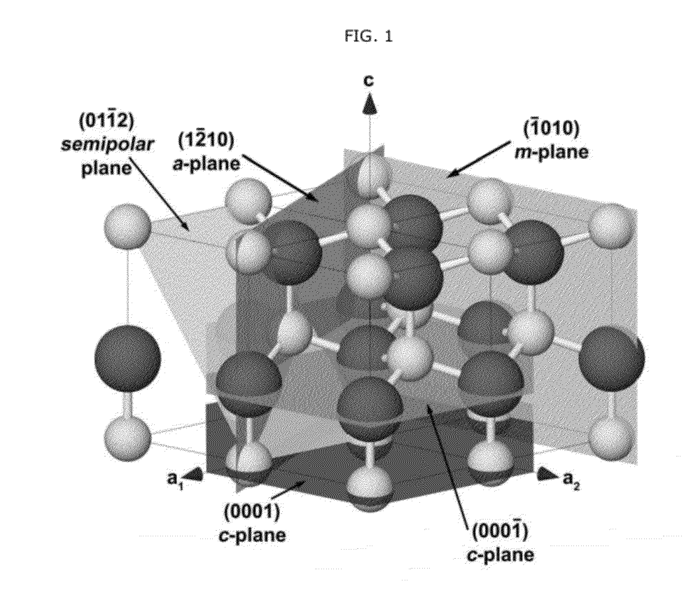

FIG. 2 is a block diagram illustrating one embodiment of methodology for the creation of free-standing nitride thin-films, thick films, or heterostructures via spontaneous separation, in accordance with the present invention.

FIG. 3 is an illustration of one embodiment of a masking method utilized in the practice of the present invention.

FIG. 4 is an illustration of an alternate embodiment of a masking method utilized in the practice of the present invention.

FIG. 5 is a scanning electron micrograph revealing the corrugated fracture surfaces where the spontaneous separation process of the present invention occurred to produce a free-standing a-plane GaN substrate.

### DETAILED DESCRIPTION OF THE PREFERRED EMBODIMENT

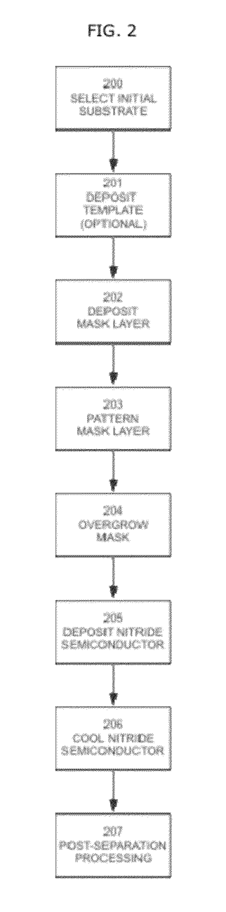

Referring now to FIG. 2, one embodiment of a basic process flow for the practice of the present invention is shown. Block 200 represents the selection of an appropriate initial substrate for growth of a free-standing nitride semiconductor, An optional role of the initial substrate of 200 is to provide a good lattice match to the orientation of a nitride template layer of 201 or a nitride semiconductor of 205 such that a nitride film can be grown upon the substrate. Suitable initial substrates for producing free-standing nitride semiconductors via spontaneous separation include, for example, (100) γ-LiAlO₂, {1 1̅00} 4H-SiC, and {1 1̅00} 6H-Sic. Other exemplary initial substrates that are suitable choices of dissimilar substrates for producing free-standing nitride semiconductors via spontaneous separation include {10 1̅2} Al₂O₃, {11 2̅0} 4H-SiC, and {11 2̅0} 6H-SiC. (Al_{z}B_{y}In_{z}Ga_{1-x-y-z})N substrates are also suitable initial substrates for the practice of the present invention, though preferably the chemical composition of the substrate is different from that of the nitride semiconductor to be grown. It should be noted that the above examples do not limit the range of applicable initial substrates. Additional suitable initial substrates include, but are not limited to, {0001} c-plane Al₂O₃, {1 1̅02} r-plane Al₂O₃, {1 1̅00} m-plane Al₂O₃, {11 2̅0} a-plane Al₂O₃, {0001} c-plane SiC, {1 1̅00} m-plane SiC, {11 2̅0} a-plane SiC, any semipolar plane of SiC, (100) γ-LiAlO₂, (100) MgAl₂O₄, (110) MgAl₂O₄, (111) MgAl₂O₄, and the like. One skilled in the art will recognize that other examples of Materials can be used in accordance with the present invention without limiting its applicability.

Generally speaking, any substrate upon which it is possible to grow the nitride semiconductor having the desired orientation may serve as the initial substrate of 200. However, it is preferred that the initial substrate be dissimilar to the nitride semiconductor to be grown with respect to thermal expansion coefficient, insofar as the present invention has proven to be most effective when the dissimilar substrate contracts at a different rate than the nitride semiconductor film when cooling from the nitride growth temperature.

Block 201 depicts the optional step of depositing a nitride semiconductor template layer upon the initial substrate. While deposition of such a template layer comprising a nitride semiconductor is not strictly required for the practice of the invention, use of such a template layer may improve the reproducibility of the spontaneous separation process and enhance the quality of the nitride semiconductor to be grown in block 205 below. The nitride semiconductor template may be deposited by any crystal growth method that is capable of producing nitride semiconductor films, including but not limited to hydride vapor phase epitaxy (HVPE), metalorganic chemical vapor deposition (MOCVD), molecular beam epitaxy (MBE), plasma-enhanced chemical vapor deposition, liquid-phase epitaxy, or sputtering. The nitride semiconductor template layer will preferably comprise a high-quality, highly-oriented, single-crystal nitride semiconductor material, more preferably of a similar composition to the nitride semiconductor to be grown. The thickness of the template layer may range from approximately 0.005 μm to approximately 500 μm. For example, in the production of a free-standing a-plane GaN substrate via the present invention, it may be desirable to deposit an approximately 20 μm thick a-plane GaN template via HYPE on an r-plane sapphire substrate. However, it is acceptable for the template layer to consist of low-quality, even polycrystalline material, or have a dissimilar composition to the nitride semiconductor to be grown. As a further example, an approximately 0.05 μm polycrystalline aluminum nitride nucleation layer template deposited by MOCVD could be utilized as a template layer for the purposes of the invention. It should further be understood that the “template layer” may in fact comprise multiple layers of varying composition, or a single layer of varying composition. For example, the template layer could comprise several pairs of layers of alternating GaN and AlGaN composition, each sub-layer being about 0.1 μm in thickness.

Block 202 represents deposition of a mask layer. Any material that resists deposition of the nitride semiconductor material to be subsequently grown is acceptable for this mask layer. In a preferred embodiment, the mask material is a dielectric material, most preferably SiO₂. The mask layer thickness may vary from roughly about 0.05 to about 50 μm, though the thickness should preferably be about 0.11 to about 0.15 μm, and most preferably approximately 0.130 μm in thickness. Other possible mask materials include, but are not limited to, W, TiN, SiₓN_{y}, HfO₂, and other dielectric and high-melting temperature metallic materials, The deposition method for the mask layer will depend on the composition and desired thickness of the mask layer. The preferred deposition technique for SiO₂ masks is plasma-enhanced chemical vapor deposition. However, electron beam evaporation, inductively coupled plasma deposition, and sputtering can also be used and have been demonstrated to be effective for this deposition step.

Block 203 represents patterning the mask layer of 202 to selectively expose regions of the underlying nitride template layer of 201 or substrate of 200 (in the absence of a template layer). The patterning technique will generally utilize conventional photolithographic processing techniques coupled with an established etching technique that is suitable for the chosen mask material. In the preferred embodiment, in which a SiO₂ mask is used, conventional wet eching with an aqueous 10% HF solution is a simple and effective mask etching technique.

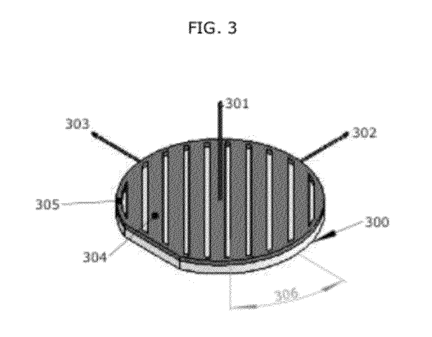

A variety of mask geometries may be used for the patterning step 203 in the practice of the present invention. The choice of mask geometries will depend primarily on the desired crystallographic orientation of the nitride film to be grown upon the mask layer. A preferred mask geometry is depicted in FIG. 3 discussed below, which includes parallel stripe openings oriented at a specified angle with respect to the major crystallographic directions of the nitride semiconductor film, surrounded by a ring of mask material. However, one skilled in the art will recognize that many other mask geometries are useful in the practice of the invention, For example, the invention has been practiced with the omission of the outer ring of mask material, or with a mask pattern containing an array of circular openings.

Block 204 represents an optional overgrowth of the mask layer with a nitride semiconductor material. The material deposited during this step is sometimes referred to herein as the “overgrowth material.” This step involves the selection of a nitride film composition, most preferably GaN though any nitride composition satisfying the formula (AlₓB_{y}In_{z}Ga_{1-x-y-z})N, in which 0≦x≦1, 0≦y≦1, 0≦z≦1, and 0≦x+y+z≦1 that does not deposit on the mask material of Block 202 is acceptable. A growth technique must also be selected for the overgrowth of the nitride layer. HVPE is the preferred growth technique, though MOCVD is also a suitable technique. Other growth methods can also be used, provided that they demonstrate growth selectivity between the open and mask-covered areas. This overgrowth step may follow previously disclosed methods, such as those described in U.S. Pat. No. 7,220,658, which is incorporated by reference herein in its entirety. The exact method of conducting the thick growth step illustrated by Block 204 is immaterial to the practice of the invention so long as the growth process yields an overgrowth as described herein. The nitride semiconductor overgrowth step involves growth of the nitride film vertically through the openings in the mask layer, then laterally or in a multi-directional fashion over the mask layer. The overgrowth process is continued until adjacent portions of the growing nitride layer converge with one another above the mask layer, forming a continuous overgrowth layer. it should be noted that the composition of the nitride semiconductor grown in Block 204 need not be identical to the nitride semiconductor(s) grown in Block 205 below, nor does the composition of the nitride semiconductor grown in Block 204 need to be of uniform composition. It is desirable that the overgrowth layer in Block 204 be less than about 20 μm thick. However, it is acceptable for the practice of this invention that the overgrowth layer range from approximately 1 μm to approximately 10,000 μm in thickness.

Block 205 represents subsequent growth of a nitride semiconductor that is desired in free-standing form. During this step, a nitride semiconductor material between about 1 and about 50,000 μm in thickness is deposited upon the overgrowth material. Provided that the total. thickness of the nitride semiconductor of 205 and the overgrowth layer of 204 exceeds 20 μm cumulatively, practically any thickness of the nitride semiconductor of 205 is acceptable for the practice of this invention. More preferably, the thickness of the nitride semiconductor 205 should range from about 20 μm to about 20,000 μm. Most preferably, the thickness of the nitride semiconductor 205 should be about 200 to about 500 μm.

The nitride semiconductor grown as represented by block 205 need not have the same composition as that of the overgrowth layer of 204. Most commonly, the composition of the nitride semiconductor of 205 will be predominantly GaN, as would generally be the case if the desired end product being produced via the present invention is a free-standing nonpolar GaN substrate. Alternately, the nitride semiconductor could consist predominantly of AlN, or any other nitride semiconductor composition satisfying the formula (AlₓB_{y}In_{z}Ga_{1-x-y-z})N, in which 0≦x≦1, 0≦y≦1, 0≦z≦1, and 0≦x+y+z≦1, exclusive of trace dopants or impurities, in an alternate product embodiment of the invention, the nitride semiconductor of 205 could comprise multiple nitride semiconductor layers of dissimilar compositions, such as may be found in the active region of a light emitting diode structure.

Preferably, the growth technique utilized in Block 205 should be the same as that used for the overgrowth step represented by Block 204. However, it is possible to utilize different growth techniques for the depositions represented by Blocks 204 and 205, For example, the overgrowth 204 could be performed by MOCVD while the nitride semiconductor deposition 205 could be performed with HVPE. Any combination of growth techniques may be used for the practice of the invention provided that they individually meet the requirements for growth techniques described throught this process flow.

Because thermal stresses are utilized in the spontaneous separation process of the present invention, it is desirable that the overgrowth material of 204 not be cooled more than 600° C. during the overgrowth step relative to the deposition temperature for growth of the nitride semiconductor represented by Block 205, Preferably the temperature difference between the overgrowth step 204 and the nitride growth 205 should be nearly zero. However, it is possible to cool the overgrowth material to room temperature prior to the nitride semiconductor growth 205 if necessary, such as to characterize the overgrowth or transfer the overgrowth from one growth tool to another. If such cool-down is required by the user, it is desirable to cool the overgrowth material 204 as slowly as possible to room temperature. Cooling rates of less than 10° C. per minute are desirable, and rates of less than 1° C. per minute are preferred to ensure that the overgrowth material 204 does not spontaneously separate from the underlying material. Further, if such cool-down is necessary, thinner overgrowth material layers have exhibited greater survivability than thicker ones. In such an instance, an overgrowth thickness of about 0.5 to about 20 μm provides the greatest chance of cool down without inducing spontaneous separation.

Block 206 represents cooling the materials thus grown from the final deposition temperature to a lower temperature so as to intentionally induce spontaneous separation of the overgrowth material of 204 and nitride semiconductor of 205 from the underlying template of 201 or substrate of 200. The temperature differential between the deposition temperature and the lower temperature should be between about 400 and about 1400° C. More preferably, the temperature differential should range from about 800 and about 1200° C. Most preferably, the temperature differential should range from about 1000 to about 1100° C. During the cool-down step 206, thermal stresses will develop due to the difference in thermal expansion coefficients of the nitride semiconductor of 205 and the initial substrate of 200. These thermal stresses will be concentrated in the areas through which the overgrowth material of 204 grew up through the openings in the mask layer of 202, since the mask material is explicitly selected such that the overgrowth material of 204 adheres poorly or not at all to it. The stress concentration in the portion of the overgrowth material extending through the mask openings causes shearing of the overgrowth material to relieve the thermal stresses, causing the nitride semiconductor of 205 and overgrowth material of 204 to spontaneously separate from the initial substrate/template layer near the mask-template/substrate interface. The process described by the flow chart in FIG. 2 thus yields the desired free-standing nitride semiconductor.

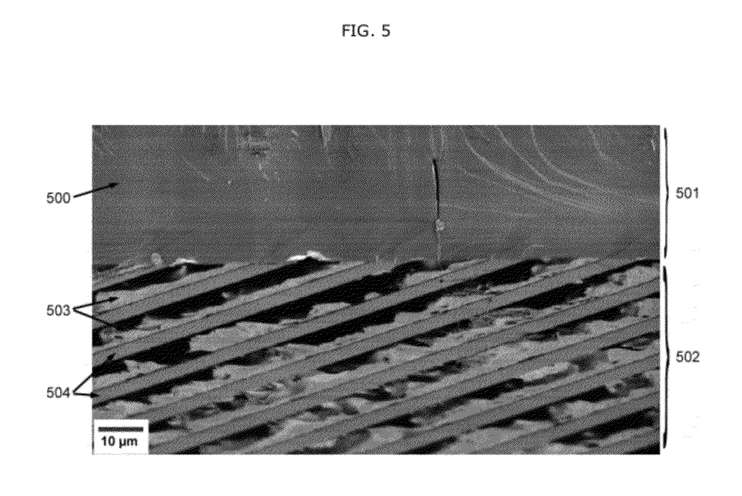

Block 207 represents optional post-separation processing of the free-standing nitride semiconductor. Most commonly, Block 207 will represent modest lapping or polishing of the surface where the overgrowth material sheared off of the underlying substrate 200 or template 201. FIG. 5 provides an image of the separation surface for one example of this spontaneous separation process. So as to provide a usable product for subsequent use, it would be desirable to polish this corrugated surface to a smooth surface for subsequent handling. Other types of post-separation processing, including but not limited to grinding, dry etching, wet etching, further patterning, or deposition of other materials, can all be incorporated into this process without fundamentally deviating from the scope of the present invention.

FIG. 3 depicts a preferred mask geometry for the practice of the invention. Block 300 represents the initial substrate and/or template, as is deemed appropriate as described with reference to FIG. 2. Blocks 301, 302, and 303 represent the primary crystallographic directions in the substrate. Block 304 represents a mask layer (as described in Block 202 above) that has been patterned as described in Block 203 above. In this embodiment, the mask pattern primarily comprises a series of parallel stripe openings. Also notable in the pattern 304 is the inclusion of a continuous ring of mask material extending to the edges of the substrate 300, called out separately as Block 305. Though the invention has been demonstrated successfully in the absence of such a mask ring 305, the presence of the mask ring enhances the invention by reducing the adhesion area of the overgrowth and nitride semiconductor (as described by Blocks 204 and 205 above) to the substrate or template 300. Block 306 represents the angle between the long axis of the mask stripes and one of the principal crystallographic directions.

The actual choice of substrate 300 with substrate orientation as represented by the crystallographic directions 301, 302, and 303 and stripe orientation angle 306 is determined by the desired orientation of the nitride semiconductor to be grown. In one preferred embodiment in which the production of a free-standing a-plane GaN substrate is desired, the substrate 300 can be an r-plane sapphire substrate, or an r-plane sapphire substrate coated with an a-plane GaN template layer. In this embodiment, direction 301 is the r-plane surface normal, direction 302 corresponds to the sapphire [0 1̅10] direction, and direction 303 corresponds to the sapphire [11 2̅0] direction. The angle 306 between the mask opening stripes and direction 302 is preferably 43°±20°; more preferably the angle 306 is between about 35° and about 55°.

A particularly favorable embodiment of the invention for production of free-standing gallium nitride can be realized by selecting an r-plane sapphire substrate as the substrate 300, and an angle 306 such that the stripes in the mask 304 are oriented at approximately 43.2°±5° relative to the sapphire [11 2̅0] direction, Such an orientation results in the mask stripes being approximately parallel to the gallium nitride [0 1̅10] direction in the overgrowth material. This geometry yields especially consistent spontaneous separation via the present invention. An additional advantage of this stripe orientation is that the overgrowth process tends to occur more rapidly and with less thickness required tor coalescence (planarization) than is commonly observed for other mask geometries.

It should be noted that while the crystallographic directions 301, 302, and 303 and angle 306 are being referenced to the substrate, it is perfectly reasonable to reference these geometric items to directions and/or angles in the template layer if present, or in the overgrowth or nitride semiconductor growth layers. Indeed, the directions in the nitride layers are related to those in the substrate via well established crystallographic relationships known to those skilled in the art.

In the particular embodiment illustrated in FIG. 3, the geometry of the mask pattern 304 comprising an array of parallel stripes of mask material can be described by specifying the width of the gap between two adjacent stripes and the width of each stripe. The gap width preferably ranges from about 0.1 to about 100 μm, and more preferably ranges from about 1 to about 10 μm. The stripe width preferably ranges from about 0.1 to about 5000 μm, and more preferably ranges from about 5 to about 500 μm, In two particularly advantageous embodiments, gap openings of about 5 μm coupled with stripe widths of about 35 and about 55 μm, respectively, have proven particularly favorable in the practice of the invention. It should be noted that while the preceding description has implied that a uniform periodic pattern of repeating gaps and stripes is used, it is not strictly necessary that the such uniformity or consistency be incorporated into the mask. One skilled in the art will recognize that any combination of multiple gap widths and stripe widths within a single mask (whether periodically repeated or not) could be used in the practice of the invention, Indeed, in one embodiment, it is beneficial to increase the stripe width towards the outer edges of the mask relative to the center of the mask so as to reduce contact area between the overgrowth or nitride semiconductor growth layers and underlying substrate/template near the outer edge. While not wishing to be bound by any particular theory, it is likely that bowing stresses are lower at the outer edge as a result of the sample being unconstrained at that location at its free surfaces so that there is less of a driving three for separation. Therefore, it is best to minimize the contact area between the overgrowth or nitride semiconductor growth layers and the underlying substrate/template towards the outer edge to encourage separation.

Further referencing FIG. 3, the mask ring 305 represents a useful enhancement to the spontaneous separation process. The present invention has been demonstrated in the absence of such a mask ring feature; however, in some instances the overgrowth and/or nitride semiconductor will adhere to the exposed substrate/template 300 around the periphery of the mask 304. These peripheral adhesion surfaces may, in some instances, lead to cracking or complete fracture of the spontaneously separated nitride semiconductor, yielding free-standing nitride semiconductor fragments that are undesirably small. While these smaller fragments can still be useful for some product embodiments it is generally more desirable for the spontaneous separation process to yield a single continuous freestanding nitride semiconductor body. Coating the periphery of the substrate/template 300 with mask material reduces or prevents adhesion of the overgrowth or nitride semiconductor to the substrate/template 300. By incorporating the mask ring 305, the spontaneous separation process more frequently yields intact free-standing nitride semiconductors.

The most important element of the mask ring 305 geometry is that it preferably should extend to the edges of the substrate/template 300, and more preferably should wrap around the edges of the substrate/template 300. The width of the mask ring 305, meaning the distance the ring of mask material extends inward from the outer edge of the substrate/template 300, should range from about 1 to about 10,000 μm. More preferably, the width of the mask ring 305 should range from about 10 to about 1000 μm. In some preferable embodiments, it is beneficial for the width of the mask ring 305 to be approximately equal to the anticipated thickness of the nitride semiconductor to be grown. Thus, for example, if one desires to produce a 500 μm-thick free-standing a-plane GaN nitride semiconductor via spontaneous separation, incorporation of a 500 μm wide mask ring will yield favorable separation results,

The above description of the mask ring 305 assumes that the shape of the ring approximately conforms to the geometry of the edges of the substrate/template 300. It should be noted, however, that the mask ring 305 need not be perfectly circular or conformal with respect to the substrate/template edges. Indeed, the width may vary around the perimeter of the substrate, or may even include gaps to encourage preferential delamination. One skilled in the art will recognize that a wide variety of mask ring geometries are compatible with the present invention without fundamentally deviating from its scope.

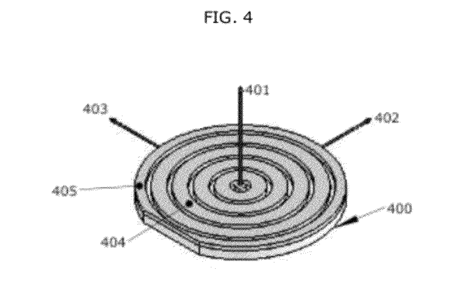

FIG. 4 provides an alternate embodiment of a preferred mask geometry for the practice of the present invention. Block 400 represents a substrate/template similar to the substrate/template 300 of FIG. 3 and blocks 401, 402 and 403 represent the directions 301, 302, and 303 as shown in FIG. 3. Block 404 represents a mask layer similar to the mask layer 304 of FIG. 3 and Block 405 represents a mask ring similar to the mask ring 305 of FIG. 3. In this particular embodiment, the mask layer comprises a series of concentric rings open to the substrate/template 400, separated by concentric rings of masking material. Similarly to the mask in FIG. 3, the ring-shaped gaps in the mask in FIG. 4 can be characterized by a gap width, and the rings of mask material can be characterized by a ring (stripe) width. The acceptable range of widths for the gaps and rings is comparable to that described above for the striped pattern in FIG. 3. Also as in FIG. 3, the mask in FIG. 4 includes an optional mask ring 405 extending to the outer edges of the substrate/template 400. Parameters describing desirable mask ring geometries are comparable to those detailed for FIG. 3 above.

FIG. 5 provides an example of a scanning electron micrograph of the separation surface from a free-standing a-plane GaN substrate 500 produced via the methods of the present invention to yield an embodiment similar to that described in FIG. 3. Block 501 represents the cross-section of the free-standing nitride semiconductor, while Block 502 identifies the underside of the free-standing nitride semiconductor. The surface depicted by Block 502 can be divided into two types of features, identified by blocks 503 and 504. The wider regions, identified by Block 503, are overgrowth material that did not adhere to the mask layer. The narrower, rougher regions identified as Block 504, are the fracture surfaces where the overgrowth material sheared from the underlying template. While the corrugations on the sheared surface are on the order of only a few microns high, it may be preferable to polish this sheared surface as described in Block 207 of FIG. 2 above. Such post-separation surface treatment utilizing conventional polishing methods will yield a free-standing substrate that is highly desirable for subsequent use in the production of nitride semiconductor devices such as light emitting diodes or laser diodes.

A variety of product embodiments can be fabricated using the methods of the present invention. The purpose of the invention is to yield free-standing nitride semiconductors, whether they are substrates, thin films of singular composition, thin films of varying or multiple compositions, or a combination of the above, via spontaneous separation. The principal advantages of the invention over the prior art include the ease of processing required to effect the removal of the initial substrate, the improved reliability and uniformity of the separation process, the ability to prevent cracking or fracture of the free-standing nitride semiconductor, and the potentially high yield associated with the separation process compared to the prior art.

The most common desired product to be produced via the invention is a free-standing nitride semiconductor substrate. Examples above described embodiments that may be performed to yield free-standing a-plane gallium nitride substrates via spontaneous separation. An alternate product embodiment is the production of a free-standing m-plane GaN substrate via spontaneous separation. Another product embodiment would be the production of a free-standing semipolar GaN substrate via spontaneous separation. Additional product embodiments include free-standing substrates produced via spontaneous separation having compositions generally described by the formula (AlₓB_{y}In_{z}Ga_{1-x-y-z})N, in which 0≦x≦1, 0≦y≦1, 0≦z≦1, and 0≦x+y+z≦1.

Free-standing device layers or heterostructures may be produced via the present invention as well. The most preferable method for such free-standing heterostructure production involves following the steps described in FIG. 2, but during the nitride semiconductor growth step growing a supporting layer such as GaN either preceding or following the growth of the heterostructure layers. The supporting layer can range in thickness from as little as 5 nm to over 5000 μm, depending on the desired application for the nitride semiconductor.

Functional optoelectronic and electronic devices, such as blue, green, and white light emitting diodes and blue and green laser diodes, among others, may benefit from this invention in that they may be formed via heterostructures that are spontaneously separated from their initial substrates. Four such examples include the formation of resonant cavity LEDs, vertical cavity surface emitting lasers, and more generally edge-emitting, lasers and light emitting diodes. It is common in the production of such optoelectronic devices to remove the initial substrate so as to “flip-chip” mount the device layer structure to enhance device performance. Optionally, electrical contacts may be deposited on the newly separated surface to enhance injection of electrical carriers into the device. The present invention provides a comparably simple method to remove the initial substrate in conjunction with the growth of the nitride semiconductor layers that make up the device itself.

The following example illustrates certain embodiments of the present invention, and is not to be construed as limiting the present disclosure.

### EXAMPLE

The free-standing a-plane GaN substrate 500 shown in FIG. 5 and discussed above was produced according to the following procedure. An r-plane sapphire substrate was initially coated with a 17 μm-thick GaN template film grown by hydride vapor phase epitaxy. Plasma-enhanced chemical vapor deposition was then used to deposit a 1400 Å-thick silicon dioxide mask layer upon the template. The template was then spin-coated with photoresist and exposed to UV light through a mask containing parallel 35 μm-wide bars separated by 5 μm-wide gaps. The sample was oriented so that the stripes would be oriented approximately 45° from the GaN [0001] axis. The exposed sample was heated for one minute to cure the photoresist, after which the pattern was developed in photoresist developer, yielding a photoresist pattern of roughly 5 μm-wide parallel gaps separated by 35 μm-wide stripes. The patterned sample was then etched in a 10% hydrofluoric acid solution for 75 seconds and rinsed in deionized water to remove the exposed SiO₂ that was not covered by photoresist. The remaining photoresist was removed by ultrasonic cleaning in acetone for two minutes, isopropanol for two minutes, and finally deionized water for two minutes. The patterned wafer was then dried with clean nitrogen and loaded into a hydride vapor phase epitaxy growth system. The wafer was heated in a mixture of ammonia and nitrogen to 1054° C. over the span of 60 minutes, after which GaN was deposited for 300 minutes. During the early stages of this deposition cycle, GaN nucleated on the exposed GaN in the window regions, grew upward through the mask layer, and laterally over the mask until they coalesced. Upon coalescence, the GaN film grew normal to the film surface to a thickness of approximately 201 μm. Following the deposition step, the sample was cooled from 1054° C. to 313° C. in 46 minutes (a cooling rate of approximately 16° C./minute) in an ammonia/nitrogen atmosphere, after which the sample was cooled to approximately 150° C. over a 40 minute span in nitrogen only. The sample was then unloaded from the growth system. After resting for approximately five minutes in room air, during which time the sample cooled nearly to room temperature, the GaN film spontaneously separated from the underlying template layer at the mask-template interface, yielding a free-standing a-plane GaN substrate.

it will be understood that the present disclosure is not limited to the embodiments disclosed herein as such embodiments may vary somewhat. It is also to be understood that the terminology employed herein is used for the purpose of describing particular embodiments only and is not intended to be limiting in scope and that limitations are only provided by the appended claims and equivalents thereof.

All publications and patents mentioned herein are incorporated herein by reference for the purpose of describing and disclosing, for example, the constructs and methodologies that are described in the publications, which might be used in connection with the presently described invention. The publications discussed above and throughout the text are provided solely for their disclosure prior to the filing date of the present application. Nothing herein is to be construed as an admission that the inventors are not entitled to antedate such disclosure by virtue of prior invention.

I claim:

1. A method for the production of a. free-standing nitride semiconductor comprising:
selecting an initial substrate that is suitable for the growth of a nitride semiconductor;
depositing a mask material that provides growth selectivity for the nitride semiconductor on the initial substrate;
producing a pattern of exposed initial substrate regions within the mask material;
selectively growing the nitride semiconductor through and over the openings in the mask material; and
cooling the nitride semiconductor from its growth temperature, whereby the nitride semiconductor separates from the initial substrate.

2. The method of claim 1, wherein the material comprising the initial substrate is selected from aluminum oxide, lithium aluminate, silicon carbide, fused silica, silicon, zirconium diboride, magnesium aluminate, gallium nitride, aluminum nitride, aluminum gallium nitride, and zinc oxide.

3. The method of claim 1, wherein the mask material is silicon dioxide, halfnium oxide, silicon nitride, titanium nitride, tungsten, tungsten nitride, carbon, or titanium.

4. The method of claim 1, wherein the nitride semiconductor is grown using hydride vapor phase epitaxy, molecular beam epitaxy, metalorganic chemical vapor deposition, liquid phase epitaxy, physical vapor transport, or ammonothermal growth.

5. The method of claim 1, wherein the free-standing nitride semiconductor comprises a nitride film selected from the group consisting of a gallium nitride film, an aluminum nitride film, an indium nitride film and an aluminum gallium nitride film.

6. The method of claim 1, wherein the thickness of the free-standing nitride semiconductor is about 5 to about 50,000 μm thick.

7. The method of claim 1, wherein the predominant growth direction of the free-standing nitride semiconductor is the [11 2̅0] direction, the [0 1̅10] direction, or a semipolar direction,

8. The method of claim 1, wherein the pattern of the mask material comprises an array of parallel stripes of the mask material interspersed with gaps open to the underlying initial substrate.

9. The method of claim 8, wherein the long axis of the stripes in the mask layer are oriented 43.2°±10° from the sapphire [11 2̅0] direction towards the sapphire [0 1̅10 ] direction.

10. The method of claim 1 wherein the pattern of the mask material comprises a series of two or more concentric rings of the mask material interspersed with gaps open to the underlying substrate.

11. The method of claim 1 wherein a thick semiconductor material is deposited upon the overgrown semiconductor material.

12. A method for the production of a free-standing nitride semiconductor comprising:
selecting an initial substrate that is suitable for the growth of a nitride semiconductor;
depositing a template which comprises the nitride semiconductor on the initial substrate;
depositing a mask material that provides growth selectivity for the nitride semiconductor on the template;
producing a pattern of exposed template regions within the mask material;
selectively growing the nitride semiconductor through and over the openings in the mask material; and
cooling the nitride semiconductor from its growth temperature, whereby the desired nitride semiconductor separates from the initial substrate and the template

13. method of claim 12, wherein the material comprising the initial substrate is selected from aluminum oxide, lithium aluminate, silicon carbide, fused silica, silicon, zirconium diboride, magnesium aluminate, gallium nitride, aluminum nitride, aluminum gallium nitride, and zinc oxide.

14. The method of claim 12, wherein the mask material is silicon dioxide, halfnium oxide, silicon nitride, titanium nitride, tungsten, tungsten nitride, carbon, or titanium.

15. The method of claim 12, wherein the nitride semiconductor is grown using hydride vapor phase epitaxy, molecular beam epitaxy, metalorganic chemical vapor deposition, liquid phase epitaxy, physical vapor transport, or ammonothermal growth.

16. The method of claim 12, wherein the free-standing nitride semiconductor comprises a nitride film selected from the group consisting of a gallium nitride film, an aluminum nitride film, an indium nitride film and an aluminum gallium nitride film having a thickness of about 5 to about 50,000 μm.

17. The method of claim 12, wherein the predominant growth direction of the free-standing nitride semiconductor is the [11 2̅0] direction, the [0 1̅10] direction Or a semipolar direction.

18. The method of claim 12, wherein the pattern of the mask material comprises an array of parallel stripes of the mask material interspersed with gaps open to the underlying initial substrate.

19. The method of claim 18, wherein the long axis of the stripes in the mask layer are oriented 43.2°±10° from the sapphire [11 2̅0] direction towards the sapphire [0 1̅10] direction.

20. The method of claim 12 wherein the pattern of the mask material comprises a series of concentric rings of the mask material interspersed with gaps open to the underlying substrate.
